(19) United States
(12) Patent Application Publication
(10) Pub. No.: US 2010/0090192 A1
(43) Pub. Date: Apr. 15, 2010

(54) METHOD FOR CONTROLLED FORMATION OF THE RESISTIVE SWITCHING MATERIAL IN A RESISTIVE SWITCHING DEVICE AND DEVICE OBTAINED THEREOF

(75) Inventors: Ludovic Goux, Hannut (BE); Dirk Wouters, Heverlee (BE)

Correspondence Address: MCDONNELL BOEHNEN HULBERT & BERGHOFF LLP, 300 S. WACKER DRIVE, 32ND FLOOR, CHICAGO, IL, 60606, US

(73) Assignees: NXP, B.V., Eindhoven (NL); INTERUNIVERSITAIR MICROELEKTRONICA CENTRUM (IMEC), LEUVEN (BE)

(21) Appl. No.: 12/439,430

(22) PCT Filed: Aug. 31, 2007
(86) PCT No.: PCT/IB2007/004248

§ 371 Date: Dec. 1, 2009

Related U.S. Application Data
(60) Provisional application No. 60/841,358, filed on Aug. 31, 2006.

(51) Int. Cl. H01L 45/00; H01L 51/40; H01L 21/16; H01L 51/30; H01L 29/12; H01L 21/28

(52) U.S. Cl. 257/4; 438/99; 438/104; 257/40; 257/43; 257/E21.078; 257/E51.041; 257/E45.002; 257/E29.068; 257/E21.158

(57) ABSTRACT

For improved scalability of resistive switching memories, a cross-point resistive switching structure is disclosed wherein the plug itself is used to store the resistive switching material and where the top electrode layer is self-aligned to the plug using, for example, chemical-mechanical-polishing (CMP) or simply mechanical-polishing.

This application claims the priority of U.S. Provisional Patent Application No. 60/841,358, filed Aug. 31, 2006.

### BACKGROUND

The present invention relates to devices wherein the electrical conductivity of the device can be reversible changed in response to an electrical voltage applied over the device. In particular the invention relates to memory devices comprising organometallic materials as resistive switching material.

The evolution of the market of data storage memories indicates a growing need for ever-larger capacity ranging from gigabytes to hundreds of gigabytes or even to Terabytes. This evolution is driven, amongst others, by new data consuming applications such as multimedia and gaming. Flash memory technology, for example, which uses the shift in threshold voltage of a field effect transistor to indicate bit status, has so far been able to fulfill this scaling requirement, keeping a reasonable cost per bit. However it is expected that Flash memory technology will face severe scaling problems beyond the 45 nm technology node due to fundamental physical limitations.

Resistive switching memories constitute replacement candidates, as their physical switching mechanisms may not degrade with scaling. These types of memories comprise a resistor element that can be reversibly programmed in either a high or a low conductive state. Various materials such as transition metal oxides, organic semiconductors or organometallic semiconductors can be used to manufacture such resistor elements.

Resistive switching memories are being integrated using structures derived from the 1T/1C (one transistor/one capacitor) concept as used in dynamic RAM. The resistor element, comprising the resistive switching material, is stacked on top of a semiconductor device such as a MOS transistor, a bipolar transistor, or a diode and accessed through a bit-line. The resistor element is placed between metal lines or between the contact to the transistor and first metal level, typically within the back-end-of-line (BEOL) section of the integrated circuit.

Baek et al. discloses in “Multilayer Cross-point Binary Oxide Resistive Memory (OxRRAM) for Post-NAND Storage Application” IEDM 2005 a memory array, where the metal/switching resistive material/metal (MRM) resistor is integrated in a cross-point configuration between the contact plug and the first metal level in the back-end-of-line section. In this integration scheme the bottom-electrode contact (BEC) layer is part of the contact plug while the stack of transition metal oxide (TMO) and the top-electrode contact (TEC) layer is patterned after deposition of the two layers. The area of the resistor element is thus defined by the area of the top electrode. Furthermore the resistor element according to Baek requires insertion of additional process steps at least for forming the top electrode.

Chen et al. also discloses in “Non-Volatile Resistive Switching for Advanced Memory Applications”, IEDM 2005, Washington D.C., 5-7 Dec. 2005, a memory array using CuₓO as a resistive switching material in the resistor elements. The copper oxide is grown from the top of the copper plugs onwards. As was the case for Baek et al., the stack of the copper oxide and the top-electrode contact (TE) layer needs to be patterned after forming both layers. As etching may damage the active area of the resistor element, an overlap between the MRM element and the copper plug is needed. This overlap will limit the scaling potential of this concept.

R. Mïler et al. discloses in “Organic CuTCNQ non-volatile memories for integration in the CMOS backend-of-line: preparation from gas/solid reaction and downscaling to an area of 0.25 um²”, Proceedings of ESSDERC conference, Grenoble, France, p 216, a method for manufacturing a CuTCNQ film by corrosion of a Cu substrate by TCNQ vapor at reduced pressure. The process flow established by Müller et al consists of first forming copper islands on an oxide layer. These copper islands will be used as bottom electrode and as starting material for the growth of CuTCNQ. A CuTCNQ film is then formed on the exposed surfaces of these copper islands. Finally a top electrode is formed by depositing an aluminum layer overlying the copper pattern. This method is applicable in forming a cross-bar memory array where the copper bottom electrodes and aluminum top electrodes are formed as parallel lines running in perpendicular directions. Each overlap between a top and bottom electrode constitutes a memory element. Thus, a voltage can be applied over the CuTCNQ film between both electrodes. Although the process flow presented by Müler et al. is made compatible with CMOS backend-of-line processing, no integrated process flow is disclosed nor are any means for selecting individual memory elements.

Hence there is a need for a method to form a resistor element comprising a resistive switching layer, in particular an organic or organometallic semiconductor, which doesn't suffer from the shortcomings of the prior art.

There is a need for a method to form a resistor element comprising an organic or organometallic semiconductor as a resistive switching layer, which would facilitate the integration of resistive switching materials in CMOS compatible process flows.

There is a need for a method to form a resistor element comprising a resistive switching layer, in particular an organic or organometallic semiconductor, which would allow the further scaling of resistor arrays.

There is also a need for a method to form a resistor element comprising a resistive switching layer, in particular an organic or organometallic semiconductor, where the method allows the integration of the resistor array with means for selecting individual resistor elements and with peripheral electronic circuitry for operating the resistor array.

### SUMMARY

The invention could be formalized as follows:

In an embodiment of the invention a method is disclosed for manufacturing a resistive switching device, the device comprising a bottom electrode, a top electrode and a layer of resistive switching material contacted by the bottom electrode and the top electrode, the method comprises providing a substrate comprising the bottom electrode, providing on the substrate a dielectric layer comprising an opening exposing the bottom electrode and forming in the opening the resistive layer.

The dielectric layer comprising the opening can be provided by depositing the dielectric layer, forming a trench in the dielectric layer, and forming in the trench an opening exposing the bottom electrode.

The resistive layer and the top electrode can be formed by at least partially filling the opening with the resistive switching material and then forming in the at least partially filled opening the top electrode.

In another embodiment of the invention a method is disclosed for manufacturing a resistive switching device, the device comprising a bottom electrode, a top electrode and a layer of resistive switching material contacted by the bottom electrode and the top electrode, the method comprises providing a substrate comprising the bottom electrode, providing on the substrate a dielectric layer comprising an opening exposing the bottom electrode, forming in the opening the resistive layer, forming a dielectric layer comprising a trench exposing the resistive layer and forming in the trench the top electrode. The resistive switching materials are deposited as to at least partially fill the opening exposing the bottom electrode.

In another embodiment of the invention a method is disclosed for manufacturing a resistive switching device on a substrate, the device comprising a bottom electrode, a top electrode and a layer of resistive switching material contacted by the bottom electrode and the top electrode, the substrate comprises a first metal pattern providing the bottom electrode pattern, the method further comprises forming a dielectric layer on the substrate, forming an opening in the dielectric layer so that the opening exposes the bottom electrode, and forming the resistive layer on the exposed bottom electrode. Afterwards the top electrode is formed on the resistive layer, thereby forming a second metal pattern.

In another embodiment of the invention a method is disclosed for manufacturing a resistive switching device on a substrate, the device comprising a bottom electrode, a top electrode and a layer of resistive switching material contacted by the bottom electrode and the top electrode, the substrate comprises a first metal pattern, and the bottom electrode is provided in a via contacting the first metal pattern, the method further comprises forming a dielectric layer on the substrate, forming a trench in the dielectric layer for receiving a second metal pattern, the trench exposing the bottom electrode, forming on the exposed bottom electrode the resistive layer, and forming the second metal pattern thereby providing the top electrode.

In any of the embodiments the step of forming the top electrode comprises forming a layer of metal over the substrate, and removing metal in excess of the opening. The materials used to form respectively the top and the bottom electrode can be the same or can be different.

In another embodiment a resistive switching device is disclosed comprising a bottom electrode, a top electrode and a layer of resistive switching material contacted by the bottom electrode and the top electrode, the top electrode and the resistive layer being contained in an opening formed in a dielectric layer.

In another embodiment a resistive switching device is disclosed comprising a bottom electrode, a top electrode and a layer of resistive switching material contacted by the bottom electrode and the top electrode, the bottom electrode being formed in a first metal pattern, the top electrode being formed in a second metal pattern, the dielectric layer separating the first and the second metal pattern and comprising an opening for providing a connection between the first metal pattern and the second metal pattern, and the resistive layer being contained in the opening.

The resistive switching material in any of the embodiments can be a charge transfer complex containing an electron donor and an electron acceptor. Preferably the resistive switching material is an organic compound having a pi electron system. Preferably the organic compound is provided by TCNQ or by a derivative of TCNQ. The electron donor can be provided by the metal of the bottom electrode. Preferably the metal of the bottom electrode is selected from metals that are used in semiconductor processing. In an embodiment the metal of the bottom electrode is selected from the group of Cu, Ag or K.

The resistive switching material in any of the embodiments can be a binary metal oxide. Preferably the bottom electrode comprises copper and the binary metal oxide is a cuprous metaloxide.

The resistive switching device in any of the embodiments can be a non-volatile memory device.

### BRIEF DESCRIPTION OF THE DRAWINGS

FIG. 1 shows a schematic cross-section of a resistor element according to an embodiment and an electrical symbol.

FIGS. 2a-e shows a schematic process flow for the fabrication of a device according to the embodiment illustrated by FIG. 1.

FIGS. 3a-e shows a schematic process flow for the fabrication of a resistive switching memory device according to an embodiment.

FIGS. 4a-e shows a schematic process flow for the fabrication of a resistive switching memory device according to an embodiment.

FIGS. 5a-e shows flowcharts schematically illustrating process flows for the fabrication of a resistor element according to various embodiments.

FIGS. 6a-e shows a schematic process flow for the fabrication of a device according to a preferred embodiment.

FIG. 7 illustrates the scalability of a device according to various embodiments of the invention.

FIG. 8 illustrates a resistive switching memory device comprising a MOS transistor used as a selection element according to embodiments of the invention.

FIG. 9 illustrates an array of devices according to embodiments of the invention illustrated by FIG. 8.

### DETAILED DESCRIPTION

The present invention will be described with respect to exemplary embodiments and with reference to certain drawings, but the invention is not limited to these examples. The drawings described are only schematic and are non-limiting. In the drawings, the size of some of the elements may be exaggerated and not drawn on scale for illustrative purposes. Hence the dimensions and the relative dimensions do not necessarily correspond to actual reduction to practice of the invention. It is intended that the embodiments and figures disclosed herein be considered illustrative rather than restrictive.

Furthermore, the terms first, second, third and the like in the description and in the claims, are used for distinguishing between similar elements and not necessarily for describing a sequential or chronological order. The terms are interchangeable under appropriate circumstances and the embodiments of the invention can operate in other sequences than described or illustrated herein.

Moreover, the terms top, bottom, over, under and the like in the description and the claims are used for descriptive purposes and not necessarily for describing relative positions. The terms so used are interchangeable under appropriate circumstances and the embodiments of the invention described herein can operate in other orientations than described or illustrated herein. For example “underneath” and “above” an element indicates being located at opposite sides of this element.

The term “comprising”, used in the claims, should not be interpreted as being restricted to the means listed thereafter; it does not exclude other elements or steps. It needs to be interpreted as specifying the presence of the stated features, integers, steps or components as referred to, but does not preclude the presence or addition of one or more other features, integers, steps or components, or groups thereof. Thus, the scope of the expression “a device comprising means A and B” should not be limited to devices consisting only of components A and B. It means that with respect to the present invention, the only relevant components of the device are A and B. Like elements are referred using like numerals.

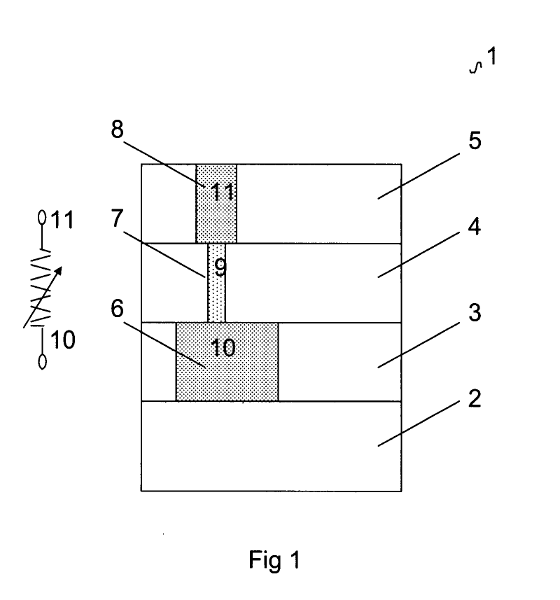

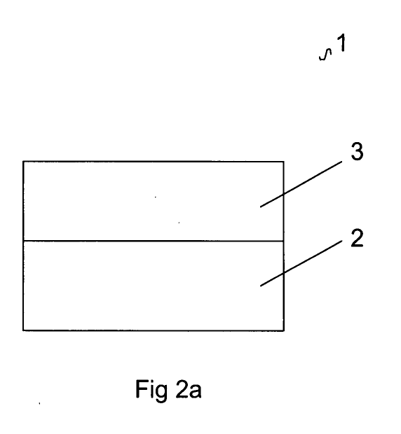

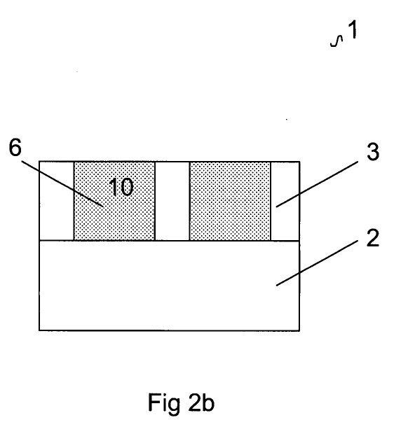

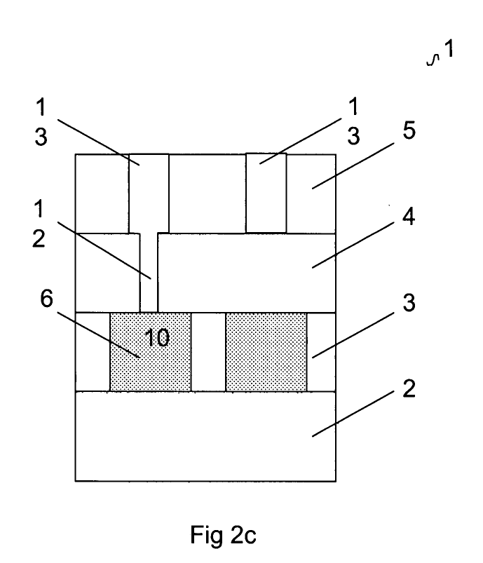

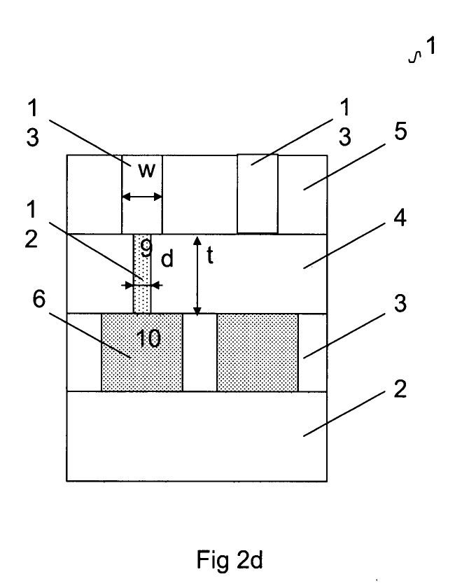

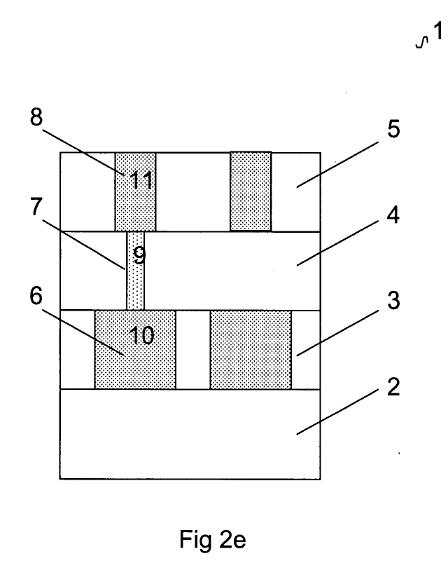

FIG. 1 shows a schematic cross-section of device 1 comprising a resistor element according to an embodiment. On a substrate 2 a stack is provided comprising multiple dielectric layers 3, 4, 5 in which metallic patterns 6, 8 are embedded at different levels. These metallic patterns 6, 8 are isolated from each other by an intermediate dielectric layer 4. Through this intermediate dielectric layer 4 an opening or via is formed to establish an electrical connection 7 between the metallic patterns 6, 8 or parts thereof which are located at different levels with the dielectric layer stack. Such a structure is known as a damascene interconnect structure because, as will be illustrated by the process flow of FIG. 2, in these dielectric layers 3, 4, 5 trenches are formed which are then filled with conductive materials. These trenches are then used to form either a metallic pattern or an electrical throughput, also known as via.

Depending on whether interlevel connection 7 and metallic patterns 6, 8 are formed individually or in combination, the respective interconnect structure is denoted as single damascene or dual damascene.

The substrate 2 can be any substrate on which such a damascene stack can be formed. Examples of such substrates includes a glass or quartz substrate, a ceramic substrate, a semiconductor substrate such as a silicon substrate, a silicon-on-insulator substrate (SOI), a germanium substrate, or a germanium-on-insulator substrate (GOI). Preferably this substrate 2 is semiconductor substrate comprising active elements 12 such as diodes and/or transistors such as field effect transistors or bipolar transistors. The interconnect structure shown in FIG. 1 is then used to establish electrical connections between individual active elements and between active elements and the bonding pads of the integrated device.

In order to make a resistor element one needs a bottom electrode, a layer of resistive switching material in contact with the bottom electrode and a top electrode in contact with the resistive switching material. In operation, a voltage drop is applied over a layer 9 of resistive switching material by applying voltages to respectively the bottom electrode 10 and the top electrode 11. Current will flow from one electrode 10, 11 through the resistive layer to the other electrode 11, 10. According to this embodiment, the layer of resistive switching material 9 establishes the electrical connection 7 between two metallic patterns 6, 8 or parts thereof. The trench formed in dielectric layer 4 is filled with resistive switching material 9 contacting at one end metallic pattern 6 and on the opposite end metallic pattern 8. The resistive switching material 9 is confined to the trench formed in the intermediate dielectric 4 and is sandwiched between the dielectric layers 3, 5 containing the metallic patterns 6, 8. Parts of the two metallic patterns 6, 8 are used as respectively the bottom 10 and top 11 electrode of the resistor element. Both electrodes are at least aligned to the electrical connection 7 which comprises the resistive switching material 9. Depending on the dimensions of the trenches formed in dielectric layers 3 and 5 the bottom electrode 10 and/or the top 11 electrode essentially overlaps the electrical connection 7. This situation is illustrated in FIG. 1.

FIGS. 2a-e illustrate by means of schematic cross-sections a process flow for manufacturing the device 1 illustrated by FIG. 1.

A substrate 2 is provided. The substrate 2 can be any substrate on which such damascene stack can be formed. Examples of such substrates include a glass or quartz substrate, a ceramic substrate, a semiconductor substrate such as a silicon substrate, a silicon-on-insulator substrate (SOI), a germanium substrate, or a germanium-on-insulator substrate (GOI). Preferably this substrate 2 is semiconductor substrate comprising active elements such as diodes and/or transistors such as field effect transistors or bipolar transistors. If the substrate 2 contains active elements, these active elements can be used to select individual resistor elements in an array of resistor elements. Typically an active element, such as a diode or a transistor is operatively linked to a resistor element such that, when in operation, only selected resistor elements are addressed. The selected resistor element is then operated, e.g. programmed, erased or read. If the substrate 2 contains active elements, then a dielectric layer is formed overlying the substrate to isolate the active elements from the interconnect structure, which will be formed upon the substrate. This dielectric layer is known as premetal dielectric (PMD).

On this substrate 2 a first dielectric layer 3 is present as shown in FIG. 2a. Typically this dielectric layer 3 contains the first level 6 of an interconnect structure, in which case this dielectric layer 3 is known as intermetal dielectric (IMD). The material of the dielectric layer 3 can be any dielectric used in semiconductor processing such as silicon oxide, silicon oxide carbide, low-k materials such as porous oxides, silicon nitride. They can be formed by deposition, e.g. chemical vapor deposition (CVD) or by coating, e.g. spin-coating.

In this dielectric 3 a first metallic pattern 6 is formed as shown in FIG. 2b. Hereto trenches are etched in the dielectric layer 3 in accordance with the pattern and the dimensions of the metallic pattern 6 to be formed. A first metallic layer is deposited overlying the patterned dielectric layer 3. Typically a stack of metallic layers is deposited to at least fill the trenches formed in dielectric layer 3. The material of the metallic pattern 6 can be Cu, Al, W, WN, Ti, TiN, Ta and/or TaN, which metals are available in state-of-the-art semiconductor technologies.

Metal in excess of the metal in the filled trenches is removed, e.g. by polishing or etch-back. Typically the substrate 2 is polished such that any metal present outside the trench is removed. One can use e.g. chemical polishing (CP) or chemical-mechanical polishing (CMP). The thus formed metallic pattern 6 provides the bottom or first electrode 10 of the resistor element.

Overlying the first metallic pattern 6 is a second dielectric layer that is formed as shown in FIG. 2c. This second dielectric layer isolates metallic patterns 6, 8 present at subsequent levels, in which case this dielectric layer is known as intermetal dielectric (IMD). In this dielectric layer, cavities 13 are formed in accordance with the pattern and the dimensions of the second metallic pattern 8 that is to be formed. Where an electrical connection 7 is to be formed between metallic patterns 6, 8, which are present at subsequent levels, the corresponding cavity 13 is extended 12 to expose the part 10 of the metallic pattern to be contacted. The extension 12 can be aligned to the trench 13, in which case the diameter d of trench 12 is of substantially the same magnitude as the width w of the trench 13. The trench 12 can be formed within the trench 13 or within the perimeter of the trench 13, in which case the diameter d of trench 12 is less than the width w of the trench 13.Typically a stack of dielectric layers 4, 5 is deposited. The trench 13 will be at least aligned to the opening 12 in which case w≧d, or will be overlapping the opening 12 in which case w>d. In each dielectric layer 4, 5 respective trenches 12, 13 are formed. The trench 12 in the dielectric layer 4 adjacent to the bottom electrode 10 will constitute a container to which the later formed resistive switching material is confined. The trenches 13 in the layer 5 overlying layer 4 will be filled with metal to form the second metallic pattern 8.

For the purpose of teaching the invention the width w of the trench 13 is made larger than the diameter d of the trench 12, in the embodiment illustrated by FIG. 2d. Typically, the trench 12 is made aligned to the trench 13 and the width w of trench 13 is substantially equal to the diameter d of the trench 12 such that the trench 13 doesn't or only slightly overlaps the trench 12. The material of the dielectric layers 4, 5 can be any dielectric used in semiconductor processing such as silicon oxide, silicon oxide carbide, low-k materials such as porous oxides, silicon nitride. They can be formed by deposition, e.g. chemical vapor deposition (CVD) or by coating, e.g. spin-coating.

In the trench 12 adjacent to the bottom electrode 10 a resistive switching material 9 is selectively formed as shown in FIG. 2d. The resistive switching material 9 will at least partially fill this trench 12. The resistive switching material 9 is confined to the trench 12 such that the resistive switching layer 9 doesn't extend beyond the trench 12. The thickness of the resistive switching layer 9 is thus equal to or less than the height of the trench 12, where the height corresponds to the thickness t of the second dielectric layer 4. Various types of material switching materials can be used to form the resistive switching layer 9.

The resistive switching layer 9 can comprise a charge transfer complex containing an electron donor and an electron acceptor. The electron acceptor is formed by an organic compound having a pi electron system. Preferably the organic compound is provided by TCNQ or by a derivative of TCNQ. The electron donor is provided by metal. Preferably this metal is Cu, Ag or K. The material of the resistive switching layer 9 may be selected from the group of organic materials and organometallic semiconductors: rotaxanes and catenanes, polyphenyleneethylenes, CuDDQ and AgDDQ wherein DDQ stands for 2,3-dichloro-5,6-dicyano-p-benzoquinone, CuTCNE and AgTCNE, wherein TCNE stands for tetracyanoethylene, CuTNAP and AgTNAP, wherein TNAP stands for tetracyanonaphtoquinodimethane, as well as AgTCNQ and CuTCNQ, wherein TCNQ stands for 7,7,8,8-tetracyano-p-quinodimethane.

Methods for growing organic semiconductors are known in the art. For example in the case of TCNQ, grow methods are e.g. disclosed by
R. S. Potember et al in “Electrical switching and memory phenomena in Cu-TCNQ thin films”, Applied Physics Letter 34(6) March 1979, in particular the formation of CuTCNQ by a reaction between metallic copper and TCNQ dissolved in acetonitrile,
U.S. Pat. No. 6,815,733 in particular the growth of CuTCNQ by thermal codeposition of Cu and TCNQ on an Al₂O₃ layer.
R. Müller et al in “Organic CuTCNQ non-volatile memories for integration in the CMOS backend-of-line: preparation from gas/solid reaction and downscaling to an area of 0.25 um²”, Proceedings of ESSDERC conference, Grenoble, France, p 216, in particular growth of CuTCNQ by corrosion of a Cu substrate by TCNQ vapor a reduced pressure,
Z Fian et al in “Silver-tetracyanoquinodimethane (Ag-TCNQ) Nanostructures and Nanodevice” in IEEE Transactions on Nanotechnology, vol 4, no 2: 238-14, March 2005, the growth of AgTCNQ either by a reaction between Ag and TCNQ dissolved in acetonitrile or by a synthesis of Ag and TCNQ in a vapor atmosphere.

Alternatively, a bistable resistive switching binary metal oxide 9, can be thermally grown on the exposed metal of the bottom electrode 10. The binary oxide can be a cuprous oxide CuₓO_{y} if copper is used to the form the bottom electrode 10. This binary metal oxide can be transition metal oxide, such as a titanium oxide. Depending on the metal exposed, an oxide such as an aluminum oxide, a tantalum oxide, a titanium oxide or a nickel oxide can be grown.

Alternatively, other resistive switching materials can be used to form the resistive switching layer 9. Examples of such other resistive switching materials are chalcogenide metals. Chalcogenides are semiconducting glasses made by elements of the VI group of the periodic table, such as Sulfide, Selenium and Tellurium. S. R. Ovshinsky and H. Fritzsche, discloses in “Amorphous Semiconductors for Switching, Memory, and Imaging Applications”, IEEE Trans. On Elec. Dev., Vol. ED-20 No. 2 February 1973, p. 91-105, hereby incorporated by reference in its entirety. In particular, paragraphs III.A and III.B of this reference discloses the discrimination between two chalcogenide material systems based on their switching properties:
(i) threshold-switching in so-called “stable” glasses that show negative differential resistance and a bistable behavior, requiring a minimum “holding voltage” to sustain the high-conductive state. The typical materials are three-dimensionally cross-linked chalcogenide alloy glasses.
(ii) memory-switching in “structure reversible films” that may form crystalline conductive paths. A typical composition is Te₈₁Ge₁₅X₄ close to the Ge—Te binary eutectic, with X being an element from group V or VI, e.g. Sb. The latter materials also show threshold switching to initiate the high conduction in the glass state, followed by an amorphous to crystalline phase transition which stabilizes the high-conductive state.

If the resistive switching layer is formed using the metal of the bottom electrode 10 as starting material, then the material of the bottom electrode 10 must be selected in view of the resistive switching material to be formed. If the resistive switching layer is formed by e.g. co-deposition of a metal, such as Cu and an organic compound such as TCNQ, the metal of the bottom electrode 10 and of the metal in the organometallic compound 9 can be different.

A second metallic layer is deposited overlying the patterned dielectric layer 4, 5 to at least fill the trenches 13 formed in dielectric layer 5. If the trench 12 is not completely filled with the resistive switching material 9, then this metallic layer will also fill the remainder of the trench 12. Typically a stack of metallic layers is deposited. The material deposited can be Cu, Al, W, WN, Ti, TiN, Ta and/or TaN.

Metal in excess of the filled trenches 13 is removed, e.g. by polishing or etch-back. Typically the substrate 2 is polished such that any metal present outside the trench is removed. One can use e.g. chemical polishing (CP) or chemical-mechanical polishing (CMP). The thus formed second metallic pattern 8 provides the top or second electrode 11 of the resistor element as shown in FIG. 2e.

FIGS. 2a-e illustrate a process module for the fabrication of a resistor element according to embodiments of the invention, the resistor element comprising a bottom electrode 10, a resistive switching layer 9 and a top electrode 11. This process module is compatible with damascene processing for fabrication of interconnect structures; in particular interconnect structures fabricated in the back-en-of-line part of semiconductor processing. The resistive switching layer 9 and the top electrode 11 are formed in the via 12 and the trench 13 of a dual damascene interconnect module whereby the resistive switching layer 9 at least partially fills the via 12. By forming an opening for receiving the resistive switching layer and the top electrode, the embodiment illustrated by FIG. 2a-e offers, inter alia, the advantage that the resistive switching layer 9 does not need to be patterned. As the resistive switching layer grows in the receiving via 12, optionally also partly in the trench 13, the geometry of this layer 9 is defined by the geometry of the via 12 and the trench 13. The latter can be done using known and proven process steps such as dielectric deposition and patterning. The top electrode 11 is afterwards formed by completing the filling of trench 13. Excess metal can be removed using polishing without affecting the resistive switching layer 9, which is protected by the top electrode 11. An advantage of this process module is that it is independent of other process modules in a process flow and hence can be inserted at various moments in the process flow. The bottom electrode (10) and the top electrode (11) can be formed using the same materials. By using the available process modules from a CMOS back-end-of-line to manufacture the bottom electrode (10) and the top electrode (11), the present invention considerably reduces the process complexity when manufacturing a resistive switching device according to any of the embodiments. The electron donor can be provided by the metal of the bottom electrode.

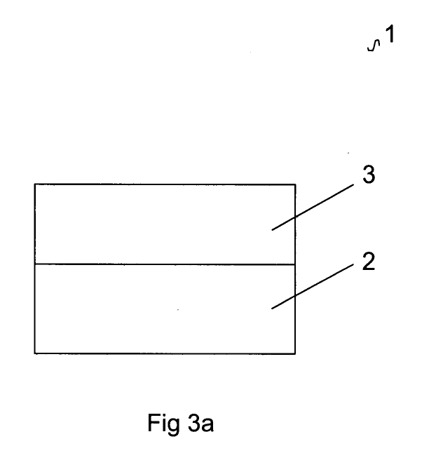

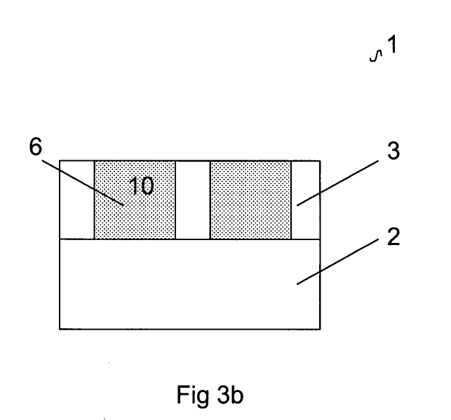

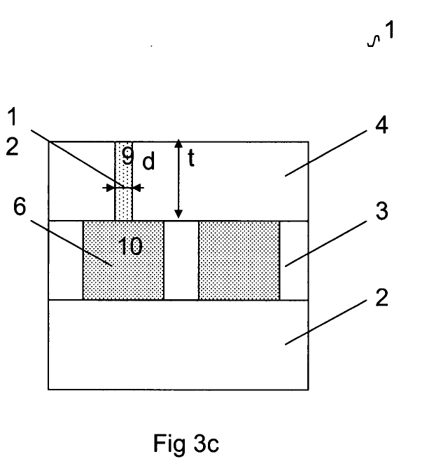

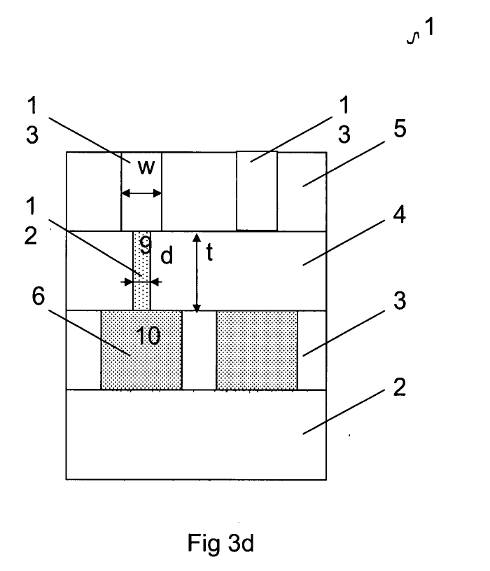

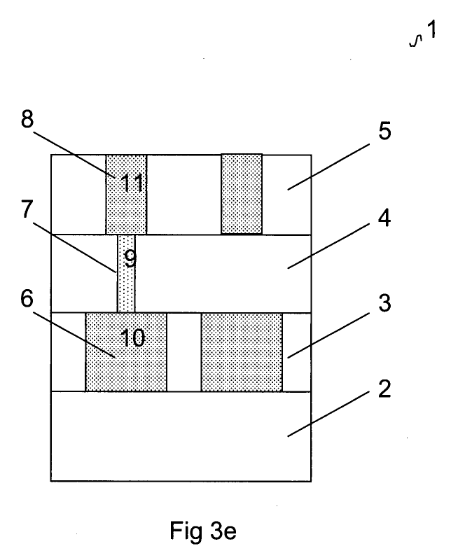

FIGS. 3a-e illustrate, by means of schematic cross-sections, a process flow for manufacturing the device 1 illustrated by FIG. 1.

A substrate 2 is provided. The substrate 2 can be any substrate on which such damascene stack can be formed. Examples of such a substrate are a glass or quartz substrate, a ceramic substrate, a semiconductor substrate such as a silicon substrate, a silicon-on-insulator substrate (SOI), a germanium substrate, or a germanium-on-insulator substrate (GOI). Preferably this substrate 2 is a semiconductor substrate comprising active elements such as diodes and/or transistors such as field effect transistors or bipolar transistors. If the substrate 2 contains active elements 12, these active elements can be used to select individual resistor elements in an array of resistor elements. Typically an active element, such as a diode or a transistor is operatively linked to a resistor element such that, when in operation, only selected resistor elements are addressed. The selected resistor element is then operated, e.g. programmed, erased or read. If the substrate 2 contains active elements than a dielectric layer is formed that overlies the substrate and isolates the active elements from the interconnect structure, which will be formed upon the substrate. This dielectric layer is known as premetal dielectric (PMD). On this substrate 2 a first dielectric layer 3 is present as shown in FIG. 2a. Typically this dielectric layer 3 contains the first level 6 of an interconnect structure in which case this dielectric layer 3 is known as intermetal dielectric (IMD). The material of the dielectric layer 3 can be any dielectric used in semiconductor processing such as silicon oxide, silicon oxide carbide, low-k materials such as porous oxides, silicon nitride. They can be formed by deposition, e.g. chemical vapor deposition (CVD) or by coating, e.g. spin-coating.

In this dielectric 3 a first metallic pattern 6 is formed as shown in FIG. 3b. Hereto trenches are etched in the dielectric layer 3 in accordance with the pattern and the dimensions of the metallic pattern 6 to be formed. A first metallic layer is deposited overlying the patterned dielectric layer 3. Typically a stack of metallic layers is deposited to at least fill the trenches formed in dielectric layer 3. The material of the metallic pattern 6 can be Cu, Al, W, WN, Ti, TiN, Ta and/or TaN.

Metal in excess of the metal in the filled trenches is removed, e.g. by polishing or etch-back. Typically the substrate 2 is polished such that any metal present outside the trench is removed. One can use e.g. chemical polishing (CP) or chemical-mechanical polishing (CMP). The thus formed metallic pattern 6 provides the bottom or first electrode 10 of the resistor element.

After providing a substrate comprising the bottom electrode 10 the resistor switching layer 9 is formed using a single damascene interconnect process module. Overlying the first metallic pattern 6, a second dielectric layer 4 is formed as shown in FIG. 3c. Typically this second dielectric layer 4 comprises multiple dielectric layers. This second dielectric layer 4 isolates metallic patterns 6, 8 present at subsequent levels, in which case this dielectric layer is known as intermetal dielectric (IMD). The material of the dielectric layer 4 can be any dielectric used in semiconductor processing such as silicon oxide, silicon oxide carbide, low-k materials such as porous oxides, silicon nitride. They can be formed by deposition, e.g. chemical vapor deposition (CVD) or by coating, e.g. spin-coating. In this second dielectric layer 4 via's are formed to expose the bottom electrodes 10. The trench 12 in the dielectric layer 4 adjacent to the bottom electrode 10 will constitute a container to which the later formed resistive switching material is confined.

In the via 12 adjacent to the bottom electrode 10 a resistive switching material 9 is selectively formed as shown in FIG. 3c. The resistive switching material 9 will at least partially fill this trench 12. The resistive switching material 9 is confined to the trench 12 such that the resistive switching layer 9 does not extend beyond the trench 12. The thickness of the resistive switching layer 9 is thus equal to or less than the height of the trench 12 which height corresponds to the thickness t of the second dielectric layer 4.

Various types of material switching materials can be used to form the resistive switching layer 9.

The resistive switching layer 9 comprises a charge transfer complex containing an electron donor and an electron acceptor. The electron acceptor is formed by an organic compound having a pi electron system. Preferably the organic compound is provided by TCNQ or by a derivative of TCNQ. The electron donor is provided by metal. Preferably this metal is Cu, Ag or K. The material of the resistive switching layer 9 is selected from the group of organic materials and organometallic semiconductors: rotaxanes and catenanes, polyphenyleneethylenes, CuDDQ and AgDDQ wherein DDQ stands for 2,3-dichloro-5,6-dicyano-p-benzoquinone, CuTCNE and AgTCNE, wherein TCNE stands for tetracyanoethylene, CuTNAP and AgTNAP, wherein TNAP stands for tetracyanonaphtoquinodimethane, as well as AgTCNQ and CuTCNQ, wherein TCNQ stands for 7,7,8,8-tetracyano-p-quinodimethane.

Methods for growing organic semiconductors are known in the art. For example in the case of TCNQ, grow methods are e.g. disclosed by
R. S. Potember et al in “Electrical switching and memory phenomena in Cu-TCNQ thin films”, Applied Physics Letter 34(6) March 1979, in particular the formation of CuTCNQ by a reaction between metallic copper and TCNQ dissolved in acetonitrile,

U.S. Pat. No. 6,815,733 in particular the growth of CuTCNQ by thermal codeposition of Cu and TCNQ on an Al₂O₃ layer.

R. Müller et al in “Organic CuTCNQ non-volatile memories for integration in the CMOS backend-of-line: preparation from gas/solid reaction and downscaling to an area of 0.25 um²”, Proceedings of ESSDERC conference, Grenoble, France, p 216, in particular growth of CuTCNQ by corrosion of a Cu substrate by TCNQ vapor a reduced pressure,
Z Fian et al in “Silver-tetracyanoquinodimethane (Ag-TCNQ) Nanostructures and Nanodevice” in IEEE Transactions on Nanotechnology, vol 4, no 2: 238-14, March 2005, the growth of AgTCNQ either by a reaction between Ag and TCNQ dissolved in acetonitrile or by a synthesis of Ag and TCNQ in a vapor atmosphere

Alternatively, a bistable resistive switching binary metal oxide 9, preferably a transition metal binary oxide, can be thermally grown on the exposed metal of the bottom electrode 10. The binary oxide can be a cuprous oxide CuₓO_{y} if copper is used to the form the bottom electrode 10. Depending on the metal exposed an oxide such as an alumina oxide, a tantalum oxide, a titanium oxide or a nickel oxide can be grown.

Alternatively other resistive switching materials can be used to form the resistive switching layer 9. Examples of such other resistive switching materials are chalcogenide metals.

If the resistive switching layer is formed using the metal of the bottom electrode 10 as starting material, then the material of the bottom electrode 10 must be selected in view of the resistive switching material to be formed. If the resistive switching layer is formed by e.g. co-deposition of a metal, such as Cu and an organic compound such as TCNQ, the metal of the bottom electrode 10 and of the metal in the organometallic compound 9 can be different.

Overlying the second dielectric layer 4, a third dielectric layer 5 is formed as shown in FIG. 3d. This third dielectric layer 5 isolates elements of the metallic pattern 8 present at the same level. Typically a stack of dielectric layers 5 is deposited. The material of the dielectric layer 5 can be any dielectric used in semiconductor processing such as silicon oxide, silicon oxide carbide, low-k materials such as porous oxides, silicon nitride. They can be formed by deposition, e.g. chemical vapor deposition (CVD) or by coating, e.g. spin-coating. In this dielectric layer 5 cavities 13 are formed in accordance with the pattern and the dimensions of the second metallic pattern 8 that is to be formed. The trench 13 can be aligned to the trench 12, in which case the diameter d of trench 12 is of substantially the same magnitude as the width w of the trench 13. For the purpose of teaching the invention the width w of the trench 13 is made larger than the diameter d of the trench 12, in the embodiment illustrated by FIG. 3d. Typically the trench 12 is made aligned to the trench 13 and the width w of trench 13 is substantially equal to the diameter d of the trench 12 such that the trench 13 doesn't or only slightly overlaps the trench 12.

The trenches 13 in the layer 5 overlying layer 4 will be filled with metal to form the second metallic pattern 8. The material of the metallic pattern 8 can be Cu, Al, W, WN, Ti, TiN, Ta and/or TaN. Metal in excess of the metal in the filled trenches 13 is removed, e.g. by polishing or etch-back. Typically the substrate 2 is polished such that any metal present outside the trench is removed. One can use e.g.

chemical polishing (CP) or chemical-mechanical polishing (CMP). The thus formed metallic pattern 8 provides the top or second electrode 11 of the resistor element as shown in FIG. 3e.

FIGS. 3a-e illustrates a process module for the fabrication of a resistor element according to embodiments of the invention, the resistor element comprising a bottom electrode 10, a resistive switching layer 9 and a top electrode 11. This process module is compatible with damascene processing for fabrication of interconnect structures; in particular interconnect structures fabricated in the back-end-of-line part of semiconductor processing. The resistive switching layer 9 is formed in the via 12 of a single damascene interconnect module whereby the resistive switching layer 9 at least partially fills the via 12. An advantage of this process module is that it is independent of other process modules in a process flow and hence can be inserted at various moments in the process flow.

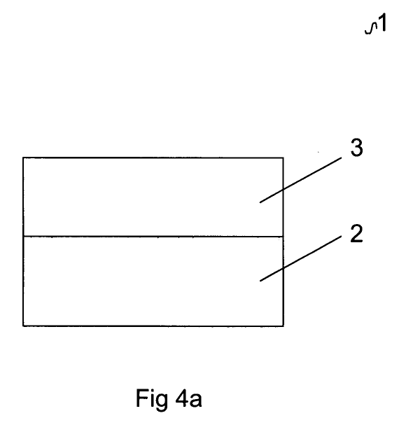

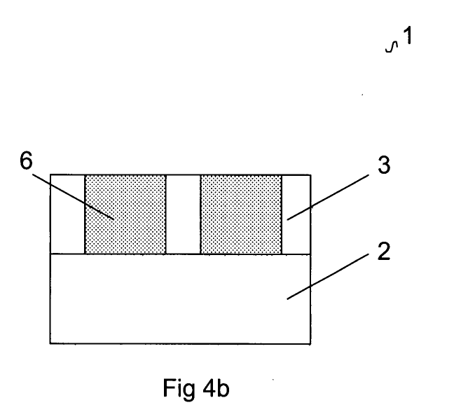

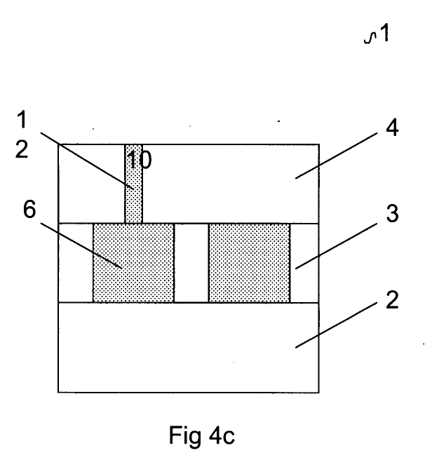

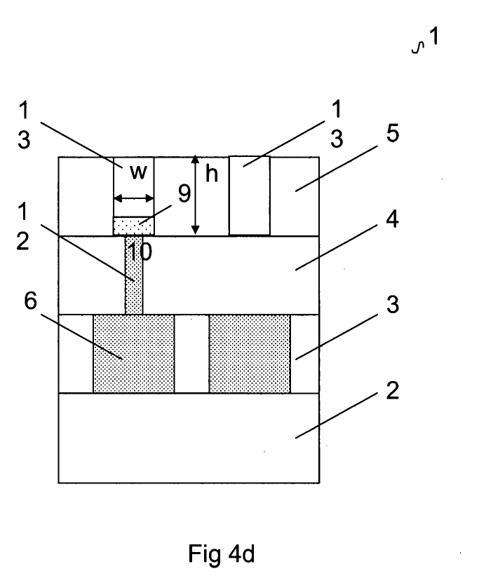

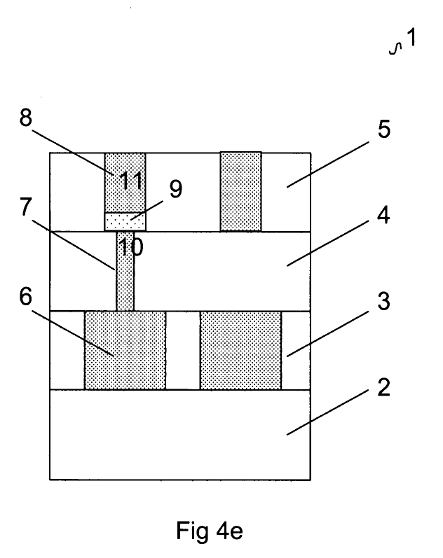

FIGS. 4a-e illustrates by means of schematic cross-sections a process flow for manufacturing the device 1 illustrated by FIG. 1.

A substrate 2 is provided. The substrate 2 can be any substrate on which such damascene stack can be formed. Examples of such substrate include a glass or quartz substrate, a ceramic substrate, a semiconductor substrate such as a silicon substrate, a silicon-on-insulator substrate (SOI), a germanium substrate, or a germanium-on-insulator substrate (GOI). Preferably this substrate 2 is a semiconductor substrate comprising active elements such as diodes and/or transistors such as field effect transistors or bipolar transistors. If the substrate 2 contains active elements 12, these active elements can be used to select individual resistor elements in an array of resistor elements. Typically an active element, such as a diode or a transistor is operatively linked to a resistor element such that, when in operation, only selected resistor elements are addressed. The selected resistor element is then operated, e.g. programmed, erased or read. If the substrate 2 contains active elements than a dielectric layer is formed overlying the substrate and to isolate the active elements from the interconnect structure which will be formed upon the substrate. This dielectric layer is known as premetal dielectric (PMD).

In this substrate 2 a first dielectric layer 3 is present as shown in FIG. 2a. Typically this dielectric layer 3 contains the first level 6 of an interconnect structure in which case this dielectric layer 3 is known as intermetal dielectric (IMD). The material of the dielectric layer 3 can be any dielectric used in semiconductor processing such as silicon oxide, silicon oxide carbide, low-k materials such as porous oxides, silicon nitride. They can be formed by deposition, e.g. chemical vapor deposition (CVD) or by coating, e.g. spin-coating.

In this dielectric 3 a first metallic pattern 6 is formed as shown in FIG. 4b. Hereto trenches are etched in the dielectric layer 3 in accordance with the pattern and the dimensions of the metallic pattern 6 to be formed. A first metallic layer is deposited overlying the patterned dielectric layer 3. Typically a stack of metallic layers is deposited to at least fill the trenches formed in dielectric layer 3. The material of the metallic pattern 6 can be Cu, Al, W, WN, Ti, TiN, Ta, and/or TaN.

Metal in excess of the metal in the filled trenches is removed, e.g. by polishing or etch-back. Typically the substrate 2 is polished such that any metal present outside the trench is removed. One can use e.g. chemical polishing (CP) or chemical-mechanical polishing (CMP). The metallic pattern 6 provides a connection to the bottom electrode 9.

After providing a substrate comprising the metallic pattern 6, a via 12 is formed using a single damascene interconnect process module. Overlying the first metallic pattern 6 a second dielectric layer 4 is formed as shown in FIG. 4c. Typically this second dielectric layer 4 comprises multiple dielectric layers. This second dielectric layer 4 isolates metallic patterns 6, 8 present at subsequent levels, in which case this dielectric layer is known as intermetal dielectric (IMD). The material of the dielectric layer 4 can be any dielectric used in semiconductor processing such as silicon oxide, silicon oxide carbide, low-k materials such as porous oxides, silicon nitride. They can be formed by deposition, e.g. chemical vapor deposition (CVD) or by coating, e.g. spin-coating. In this second dielectric layer 4 via's 12 are formed to expose the bottom electrodes 10.

The via's 12 in the layer 4 will be filled with metal to form an electrical connection towards the metallic pattern 6. The material used to fill the via 12 can be Cu, Al, W, WN, Ti, TiN, Ta, and/or TaN. Metal in excess of the metal in the filled trenches 12 is removed, e.g. by polishing or etch-back. Typically the substrate 2 is polished such that any metal present outside the trench is removed. One can use e.g.

chemical polishing (CP) or chemical-mechanical polishing (CMP). The thus formed via pattern 12 provides the bottom or first electrode 10 of the resistor element as shown in FIG. 4c.

Overlying the second dielectric layer 4, a third dielectric layer 5 is formed as shown in FIG. 4d. This third dielectric layer 5 isolates elements of the metallic pattern 8 present at the same level. Typically a stack of dielectric layers 5 is deposited. The material of the dielectric layer 5 can be any dielectric used in semiconductor processing such as silicon oxide, silicon oxide carbide, low-k materials such as porous oxides, silicon nitride. They can be formed by deposition, e.g. chemical vapor deposition (CVD) or by coating, e.g. spin-coating. In this dielectric layer 5 trenches 13 are formed in accordance with the pattern and the dimensions of the second metallic pattern 8 to be formed. The trench 13 can be aligned to the trench 12, in which case the diameter d of trench 12 is of substantially the same magnitude as the width w of the trench 13. For the purpose of teaching the invention the width w of the trench 13 is made larger than the diameter d of the trench 12, in the embodiment illustrated by FIG. 3d. Typically the trench 12 is made aligned to the trench 13 and the width w of trench 13 is substantially equal to the diameter d of the trench 12 such that the trench 13 doesn't or only slightly overlaps the trench 12.

In the trench 13 a resistive switching material 9 is selectively formed on the material filling the via 12 as shown in FIG. 4d. The resistive switching material 9 will only partially fill this trench 13. The thickness of the resistive switching layer 9 is thus less than the height of the trench 13, where the height corresponds to the thickness h of the third dielectric layer 5. A bistable resistive switching binary metal oxide 9, preferably a transition metal binary oxide, can be thermally grown on the exposed metal of the bottom electrode 10. The binary oxide can be a cuprous oxide CuₓO_{y}, if copper is used to the fill the via 12. Depending on the metal exposed an oxide such as an aluminum oxide, a tantalum oxide, a titanium oxide or a nickel oxide can be grown.

The resistive switching layer 9 comprises a charge transfer complex containing an electron donor and an electron acceptor. Methods for growing organic semiconductors are known in the art.

The trenches 13 in the layer 5 overlying layer 4 will be further filled with metal to form the second metallic pattern 8. The material of the metallic pattern 8 can be Cu, Al, W, WN, Ti, TiN, Ta and/or TaN. Metal in excess of the metal in the filled trenches 13 is removed, e.g. by polishing or etch-back. Typically the substrate 2 is polished such that any metal present outside the trench is removed. One can use e.g. chemical polishing (CP) or chemical-mechanical polishing (CMP). The thus formed metallic pattern 8 provides the top or second electrode 11 of the resistor element as shown in FIG. 4e.

FIGS. 4a-e illustrate a process module for the fabrication of a resistor element according to embodiments of the invention, the resistor element comprising a bottom electrode 10, a resistive switching layer 9 and a top electrode 11. This process module is compatible with damascene processing for fabrication of interconnect structures; in particular interconnect structures fabricated in the back-end-of-line part of semiconductor processing. The resistive switching layer 9 is formed in the trench 13 of a single damascene interconnect module whereby the resistive switching layer 9 only partially fills the trench 13. An advantage of this process module is that it is independent of other process modules in a process flow and hence can be inserted at various moments in the process flow.

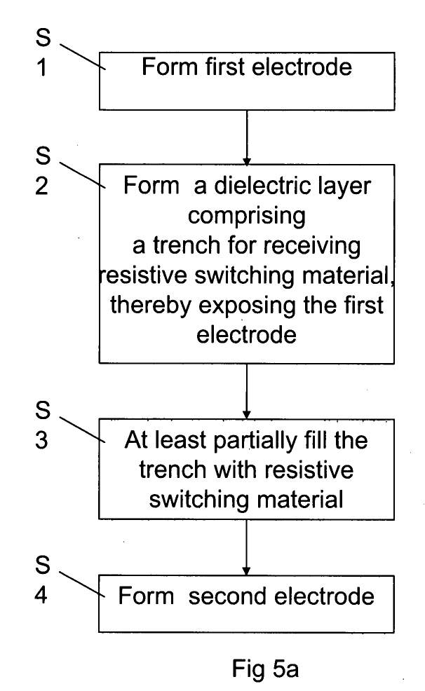

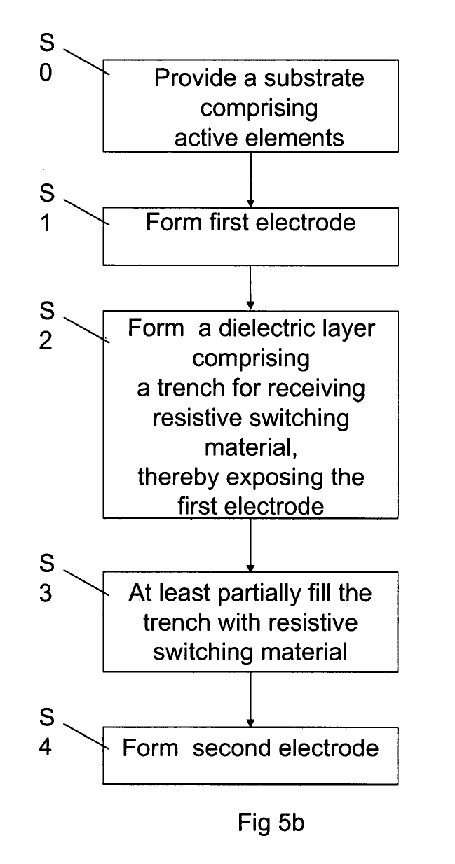

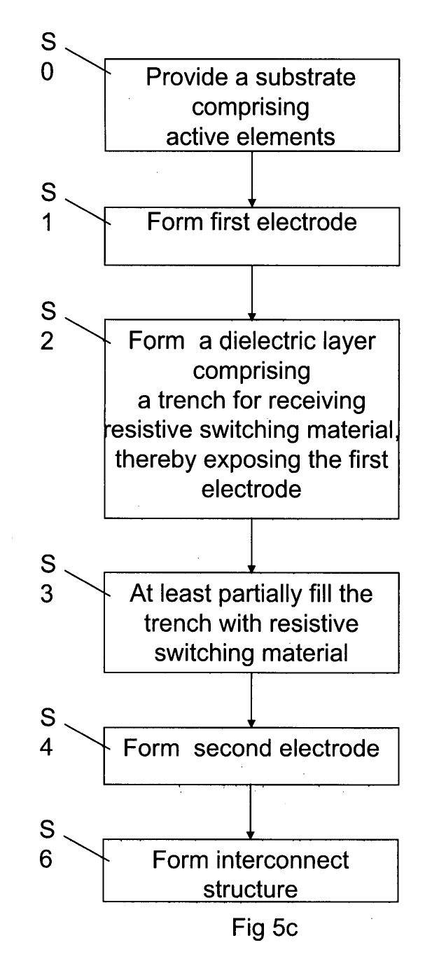

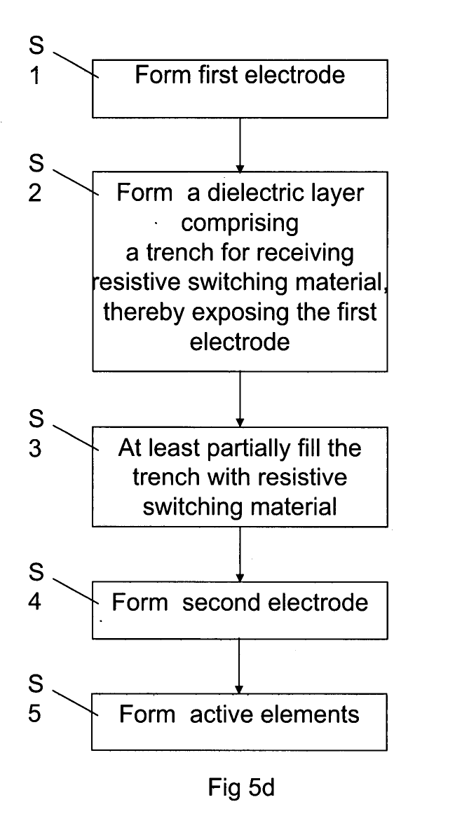

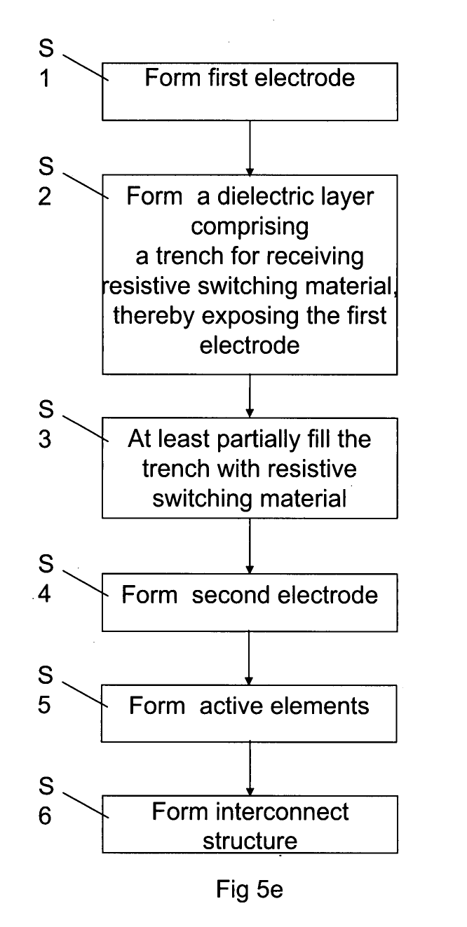

FIGS. 5a-e show flowcharts for fabricating a resistor element according to selected embodiments of the invention.

The flow chart of FIG. 5a illustrates a process module for the fabrication of a resistor element. The flow chart comprises the steps of forming S1 a first electrode 10 on a substrate 2, forming S2 a dielectric layer 4 overlying the first electrode 10, the dielectric 4 comprising a trench 12 for receiving the resistive switching material 9, the trench 12 exposing the first electrode 10, at least partially filling S3 the trench 12 with resistive switching material 9 thereby contacting the first electrode 10 and forming S4 a second electrode 11 for contacting the resistive switching material 9.

The flow chart illustrated by FIG. 5b comprises the steps of providing S0 a substrate 2 comprising active elements which will operatively linked with the resistor elements for addressing thereof, forming S1 a first electrode 10 the first electrode being in electrical contact with an active element, forming S2 a dielectric layer 4 overlying the first electrode 10, the dielectric 4 comprising a trench 12 for receiving the resistive switching material 9, the trench 12 exposing the first electrode 10, at least partially filling S3 the trench 12 with resistive switching material 9 thereby contacting the first electrode 10 and forming S4 a second electrode 11 for contacting the resistive switching material 9.

The flow chart illustrated by FIG. 5c comprises the steps of providing S0 a substrate 2 comprising active elements which will operatively linked with the resistor elements for addressing thereof, forming S1 a first electrode 10 the first electrode being in electrical contact with an active element, forming S2 a dielectric layer 4 overlying the first electrode 10, the dielectric 4 comprising a trench 12 for receiving the resistive switching material 9, the trench 12 exposing the first electrode 10, at least partially filling S3 the trench 12 with resistive switching material 9 thereby contacting the first electrode 10, forming S4 a second electrode 11 for contacting the resistive switching material 9 and forming an interconnect structure for addressing resistor elements.

The flow chart illustrated by FIG. 5d comprises the steps of forming S1 a first electrode 10 on a substrate, forming S2 a dielectric layer 4 overlying the first electrode 10, the dielectric 4 comprising a trench 12 for receiving the resistive switching material 9 the trench 12 exposing the first electrode 10, at least partially filing S3 the trench 12 with resistive switching material 9 thereby contacting the first electrode 10, forming S4 a second electrode 11 for contacting the resistive switching material 9 and forming S5 active elements, which will be operatively linked with the second electrodes for the addressing of resistor elements.

The flow chart illustrated by FIG. 5e comprises the steps of forming S1 a first electrode 10 on a substrate, forming S2 a dielectric layer 4 overlying the first electrode 10, the dielectric 4 comprising a trench 12 for receiving the resistive switching material 9 the trench 12 exposing the first electrode 10, at least partially filing S3 the trench 12 with resistive switching material 9 thereby contacting the first electrode 10, forming S4 a second electrode 11 for contacting the resistive switching material 9 and forming S5 active elements which will be operatively linked with the second electrodes for the addressing of resistor elements and forming S6 an interconnect structure to establish electrical connections to these active elements.

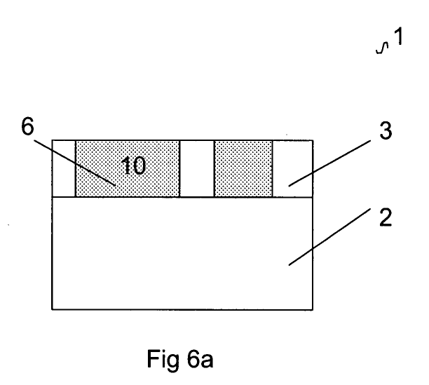

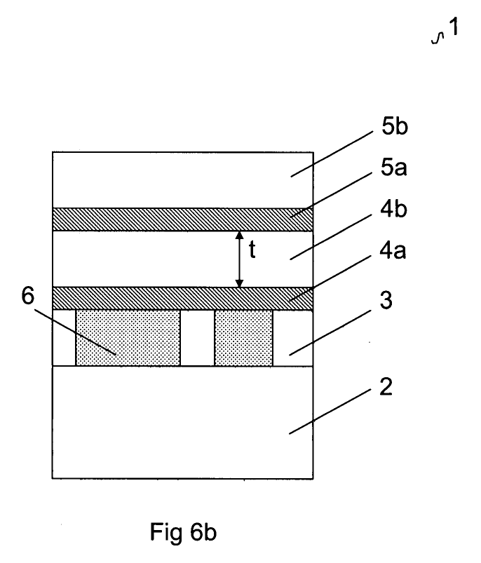

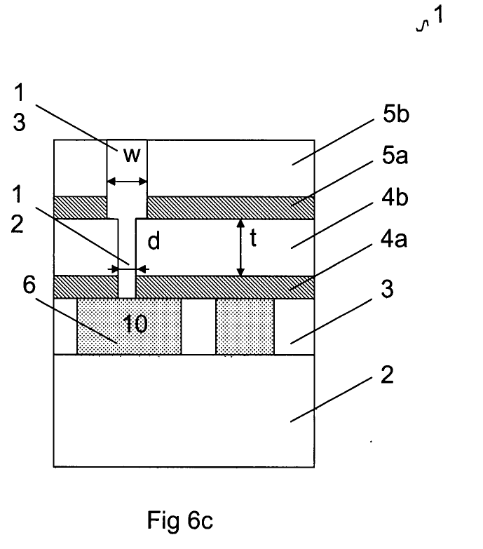

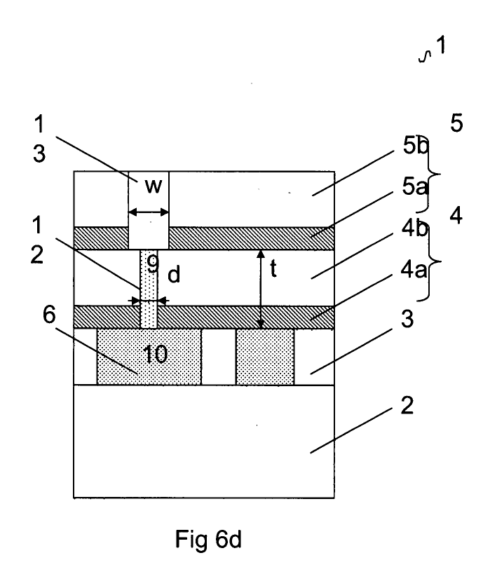

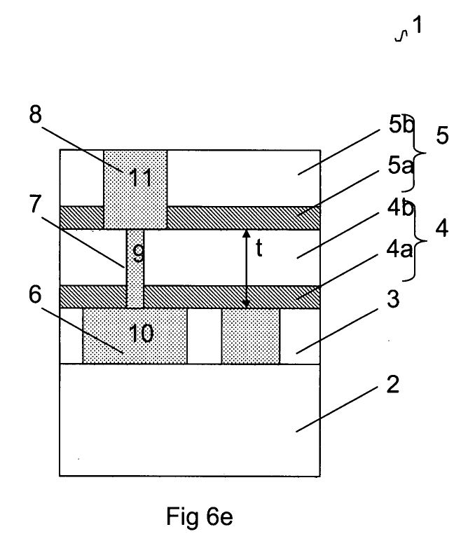

FIGS. 6a-e illustrates a preferred embodiment of the invention.

As shown in FIG. 6a a substrate 2 is provided. This substrate 2 is processed to form CMOS (Complementary Metal Oxide Silicon) devices and contacts. On this substrate a first metal pattern 6 is formed in a first dielectric layer 3. The first dielectric layer 3 is a stack of a silicon oxide layer and a silicon carbide layer. This dielectric layer 3 is photolithographically patterned to form trenches exposing the contacts (not shown in FIG. 6a). The pattern of the trenches corresponds to the pattern of the first metal pattern 6 to be formed. Then copper is deposited over the patterned dielectric layer 3, typically by first sputtering a thin layer of copper followed by electrochemical plating (ECP) copper until the trenches and the patterned dielectric layer is covered with copper. This copper layer is planarized thereby exposing the surface of the patterned dielectric layer 3 between the filled trenches thereby yielding the first metallic pattern 6. Planarization of the copper layer is typically done using chemical-mechanical polishing (CMP).

Then a second dielectric layer 4, 5 is deposited over the patterned dielectric layer 3 containing the first metallic pattern 6 as shown in FIG. 6b. Typically the second dielectric layer 4, 5 is a stack of a silicon carbide layer 4a, 5a and a silicon oxide layer 4b, 5b.

The second dielectric layer is patterned in two steps using the silicon-carbide layers 4a, 5a as etch stop layers as shown in FIG. 6c. Various approaches are known in the art and applicable to form trenches 12 for establishing an electrical contact between metallic patterns 6, 8 at subsequent levels and trenches 13 for forming another level of metallic pattern 8. In “Silicon Processing for the VLSI ERA”, by Stanley Wolf, vol 4, 2004, p 674-679, hereby incorporated by reference, dual damascene interconnect technologies are being explained. One approach is to form in a first patterning step a trench in layer 5b thereby stopping on layer 5a. This trench has a diameter d equal to the diameter of trench 12. In a second patterning step another trench 13 having width w is formed in the layer 5b. The pattern of the trenches 13 corresponds to the pattern of the second metal pattern 8 to be formed. When etching these trenches 13 the exposed layer 4b is further etched thereby forming the trench 12 in this layer 4b. Differences in etch time, e.g. due to differences in the thickness or in the composition 4b and 5b are dealt with by using layer 5a as an etch stop layer protecting the unexposed parts of layers 4b.

Inside the trench 12 the resistive switching layer 9 is formed as shown in FIG. 6d. For example CuTCNQ is grown from the bottom of the trench 12 where the first electrode 10 is exposed. This growth process can be induced by a corrosion reaction of the exposed metallic copper surface of the first electrode 10 with TCNQ in vapor phase thereby generating CuTCNQ wires growing in a controlled way in the trench 12 thereby at least partially filling the trench 12. The CuTCNQ wires are confined to the trench 12 such that the resistive switching layer 9 doesn't extend beyond the trench 12. The thickness of the resistive switching layer 9 is thus equal to or less than the height of the trench 12 which height corresponds to the thickness t of the second dielectric layer 4.

A top electrode contact 11 is formed as part of a second metallic pattern 8 as shown in FIG. 6e. Copper is deposited over the patterned dielectric layer 5, typically by first sputtering a thin layer of copper followed by electrochemical plating (ECP) copper until the trenches and the patterned dielectric layer is covered with copper. This copper layer is planarized thereby exposing the surface of the patterned dielectric layer 5 between the filled trenches 13 thereby yielding the second metallic pattern 8. Planarization of the copper layer is typically done using chemical-mechanical polishing (CMP).

Other metals such as Aluminum can also be used to form electrode 11, as the structure is typically Al/CuTCNQ/Cu.

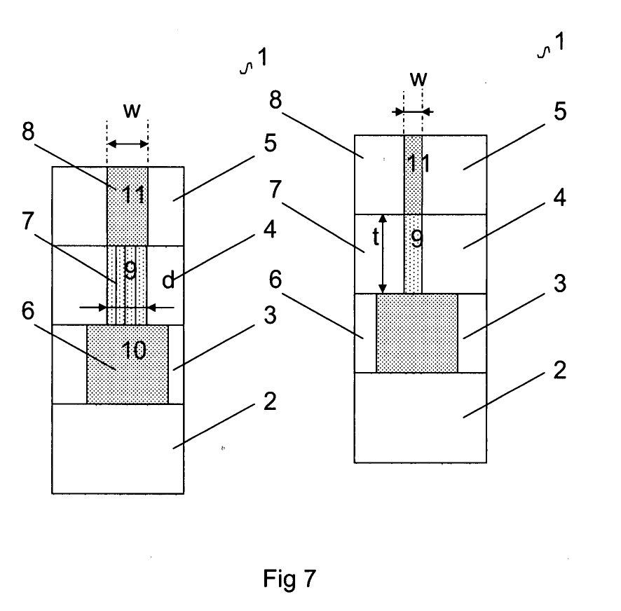

An advantage of resistor elements fabricated according to embodiments of the invention is the scalability thereof. FIG. 7 illustrates this advantage. The resistor element on the left is formed by multiple wires of resistive switching layer 9, the number of wires being dependent on the diameter d of the trench 12. In the embodiment illustrated by FIG. 7 left, 4 nanowires are grown. By reducing the diameter d of the trench 12 the number of nanowires grown in the trench 12 will decrease until only one nanowire is grown as illustrated in FIG. 7 by the resistor element on the right. The minimal diameter d of the trench 12 then corresponds to the minimal diameter of the nanowire. Another geometrical parameter that can be used to scale resistor elements according to embodiments of the invention is the thickness of the resistive switching layer 9. This thickness is determined by the thickness of the dielectric layer 4 wherein the trench 12 is formed. By reducing the thickness of this dielectric layer one can, for a given diameter of the trench 12, reduce the overall resistance of the resistor element. Hence the thickness of the dielectric layer 4 can be used to determine the resistance range of the resistor element which, e.g., has an impact on the operation voltages, read-out of signals etc.

A single resistor element or an array of resistor elements according to embodiments of the invention can be formed.

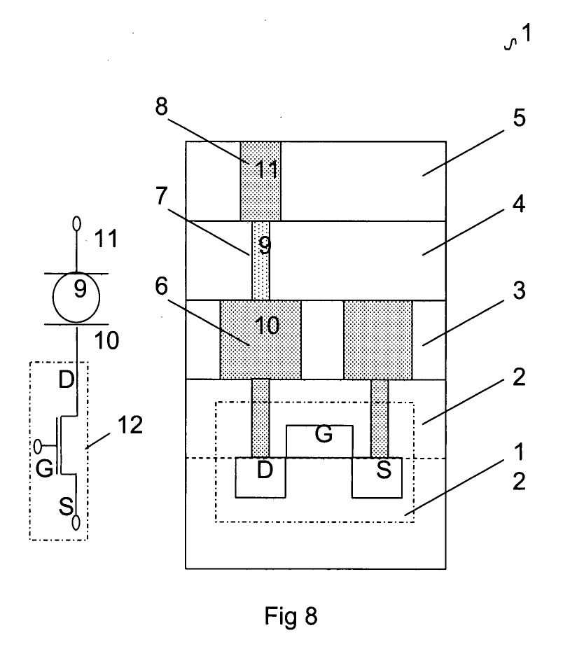

FIG. 8 illustrates a resistive switching memory device 1 formed using damascene processing according to embodiments wherein the resistive switching material is confined in a trench. The memory device 1 is selectable by a transistor 12 which is connected in series with the memory device 1. The transistor is formed in the substrate 2.

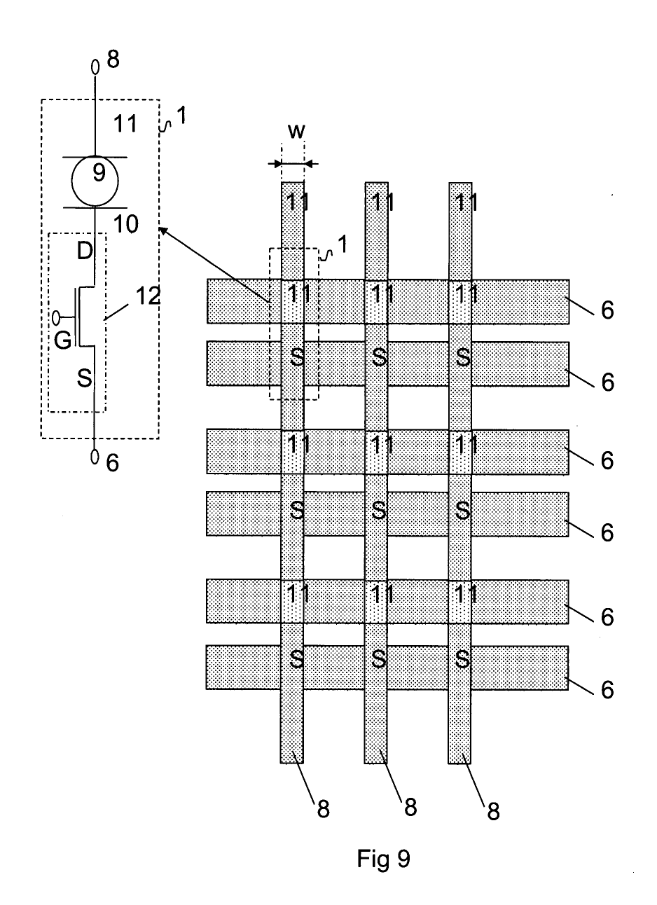

FIG. 9 shows an example of such an array of memory devices 1 according to any of the embodiments of the invention in the configuration illustrated by FIG. 8. The memory array is configured as a cross-point structure. Metal lines of a first metal pattern 6 run perpendicular to metal lines of a second metal pattern 8. As these metal patterns 6, 8 are formed at different levels the corresponding metal lines will cross each-other. For each cross-point a resistor element 10-9-11 is connected to the selection element 12 between the two metal patterns. The array configuration shown in FIG. 9 allows selection individual resistor elements. The teaching of the above embodiments can be used to form such a cross-point array.

We claim:

1. A method for manufacturing a resistive switching device, the device comprising a bottom electrode, a top electrode, and a layer of resistive switching material contacted by the bottom electrode and the top electrode, wherein the method comprises:
providing a substrate comprising the bottom electrode;
providing on the substrate a dielectric layer comprising an opening exposing the bottom electrode; and
forming, in the opening, the resistive layer.

2. The method of claim 1, wherein providing the dielectric layer comprises:
depositing the dielectric layer;
forming a trench in the dielectric layer; and
forming in the trench an opening exposing the bottom electrode.

3. The method of claim 1, wherein forming the resistive layer comprises at least partially filling the opening with the resistive layer, further comprising:
forming the top electrode in the at least partially filled opening.

4. The method of claim 1, wherein providing the dielectric layer and forming the resistive layer comprise:
forming a first dielectric layer having an opening exposing the bottom electrode; and
forming the resistive layer in the opening;
further comprising:
forming a second dielectric layer comprising a trench that exposes the resistive layer; and
forming the top electrode in the trench.

5. The method of claim 4, wherein forming the resistive layer comprises partially filling the opening with the resistive switching material.

6. The method of claim 1, wherein the substrate comprises a first metal pattern, and the bottom electrode is provided in the first metal pattern.

7. The method of claim 1, wherein the substrate comprises a first metal pattern, and the bottom electrode is provided in a via contacting the first metal pattern, further comprising:
forming the top electrode in a second metal pattern.

8. The method of claim 1, wherein the resistive switching material is a charge transfer complex containing an electron donor and an electron acceptor.

9. The method of claim 8, wherein the resistive switching material is an organic compound having a pi electron system.

10. The method of claim 9, wherein the organic compound is provided by TCNQ or by a derivative of TCNQ.

11. The method of claim 10, wherein the electron donor is provided by the metal of the bottom electrode, the metal being selected from the group consisting of Cu, Ag or K.

12. The method of claim 1, wherein the resistive switching material is a binary metal oxide.

13. The method of claim 12, wherein the bottom electrode comprises copper, and the binary metal oxide is a cuprous metal oxide.

14. The method of claim 1, further comprising forming the forming the top electrode, wherein forming the top electrode comprises forming a layer of metal over the substrate, and removing metal in excess of the opening.

15. The method of claim 1, wherein the resistive switching device is a non-volatile memory device.

16. A resistive switching device, comprising:
a bottom electrode;
a top electrode; and
a layer of resistive switching material contacted by the bottom electrode and the top electrode;
wherein the top electrode and the resistive layer are contained in an opening formed in a dielectric layer.

17. The device of claim 16, wherein:
the bottom electrode is formed in a first metal pattern;
the top electrode is formed in a second metal pattern;
the dielectric layer comprises at least a first layer and a second layer, the first layer separating the first and the second metal pattern and having an opening for providing a connection between the first metal pattern and the second metal pattern; and
the resistive layer is contained in the first opening.

18. The device of claim 16, wherein the resistive switching material is a charge transfer complex containing an electron donor and an electron acceptor.

19. The device of claim 18, wherein the resistive switching material is an organic compound having a pi electron system.

20. The method of claim 19, wherein the organic compound is provided by TCNQ or by a derivative of TCNQ.

21. The device of claim 20, wherein the electron donor is provided by the metal of the bottom electrode, the metal being selected from the group consisting of Cu, Ag or K.

22. The device of claim 16, wherein the resistive switching material is a binary metal oxide.

23. The device of claim 22, wherein the bottom electrode comprises copper, and the binary metal oxide is a cuprous metal oxide.

24. The device of claim 16, wherein the bottom electrode and the top electrode are formed from the same materials.
